(19) United States
(12) Patent Application Publication
(10) Pub. No.: US 2025/0318222 A1
(43) Pub. Date: Oct. 9, 2025

(54) SEMICONDUCTOR DEVICE AND METHOD OF MANUFACTURING THE SAME

(71) Applicant: Renesas Electronics Corporation, Tokyo (JP)

(72) Inventor: Yasutaka NAKASHIBA, Tokyo (JP)

(21) Appl. No.: 19/070,772

(22) Filed: Mar. 5, 2025

(30) Foreign Application Priority Data
Apr. 4, 2024 (JP) 2024-060850

(51) Int. Cl. H10D 62/10; H01L 21/306; H01L 21/308; H01L 23/00; H10D 30/66; H10D 62/40

(52) U.S. Cl. CPC H10D 62/127; H01L 21/30604; H01L 21/308; H10D 62/405; H01L 24/04; H01L 24/32; H01L 2224/04042; H01L 2224/32245; H10D 30/66

(57) ABSTRACT

A semiconductor device includes a semiconductor substrate having a first surface where a source terminal and a gate electrode of a vertical transistor are formed, and a second surface where a drain terminal of the vertical transistor is formed; a bonding region formed on an upper surface of a region where the source terminal is formed on the first surface side, to which a bonding wire for supplying current to the source terminal is connected; and a plurality of recesses formed in a region on the second surface, at least including the region facing the first surface where the bonding region is formed. An extending direction of an outer peripheral side of an opening of the plurality of recesses is set in a direction mismatched with an extending direction of a side of an element pattern formed on the first surface.

### CROSS-REFERENCE TO RELATED APPLICATIONS

The disclosure of Japanese Patent Application No. 2024-060850 filed on Apr. 4, 2024, including the specification, drawings and abstract is incorporated herein by reference in its entirety.

### BACKGROUND

The present invention relates to a semiconductor device, for example, a semiconductor device including a power transistor.

There are disclosed techniques listed below.
[Patent Document 1] Japanese Unexamined Patent Application Publication No. 2022-112707

In a power transistor constituted by a vertical transistor that allows current to flow in the thickness direction of the semiconductor substrate, as a measure to reduce on-resistance, it is conceivable to thin the drain region by polishing the semiconductor substrate from the second surface side, which becomes the drain terminal. Therefore, Patent Document 1 discloses a technique for thinning the semiconductor substrate.

The semiconductor device of Patent Document 1 comprises a semiconductor substrate having a first surface and a second surface opposite the first surface, a gate insulating film formed on the first surface, a gate formed on the first surface through the gate insulating film, a source region formed on the first surface side of the semiconductor substrate and formed to contact the source region, and a body region including a channel region, a drain region formed on the second surface side of the semiconductor substrate, and a drift region formed to contact the second surface side of the body region and the first surface side of the drain region. The gate is opposed to the channel region with the gate insulating film interposed. The semiconductor substrate forms at least one recess recessing toward the first surface on the second surface.

However, in Patent Document 1, when the extending direction of the side of the element pattern formed on the first surface and the extending direction of the side of the recess formed on the second surface coincide, there is a problem that the recess cannot be formed as designed during etching.

Other objects and novel features will become apparent from the description of this specification and the accompanying drawings.

A semiconductor device according to one embodiment comprises a semiconductor substrate having a first surface where a source terminal and a gate electrode of a vertical transistor are formed, and a second surface where a drain terminal of the vertical transistor is formed, a bonding region formed on an upper surface of a region where the source terminal is formed on the first surface side, to which a bonding wire supplying current to the source terminal is connected, and a plurality of recesses formed in a region on the second surface side, at least including a region facing the first surface where the bonding region is formed, wherein an extending direction of an outer peripheral side of an opening of the plurality of recesses is set in a direction mismatched with an extending direction of a side of an element pattern formed on the first surface.

A method for manufacturing a semiconductor device according to one embodiment comprises element formation of forming a transistor on a first surface of a semiconductor substrate; wiring formation of forming wiring and a bonding region related to the transistor on the first surface; surface protection layer formation of forming a surface protection layer on a surface of the wiring and the bonding region; mask pattern formation of forming a mask pattern on a second surface facing the first surface of the semiconductor substrate, corresponding to openings of the plurality of recesses; etching the exposed semiconductor substrate at the openings by wet etching with TMAH (Tetramethylammonium hydroxide); and mask pattern removal of removing the mask pattern, wherein an extending direction of a side of the openings of the mask pattern is set in a direction mismatched with an extending direction of a side of an element pattern formed on the first surface.

In a semiconductor device and a manufacturing method thereof according to an embodiment, it is possible to enhance the formation accuracy of a recess pattern formed on a second surface where a drain terminal of a vertical transistor is formed.

### BRIEF DESCRIPTION OF THE DRAWINGS

FIG. 1 is a schematic diagram of the semiconductor device according to the first embodiment.

FIG. 2 is a cross-sectional view of the semiconductor device according to the first embodiment.

FIG. 3 is a diagram explaining the relationship between the element pattern and the recess pattern formed in the semiconductor device according to the first embodiment.

FIG. 4 is a diagram explaining the anisotropic etching process used in the semiconductor device according to the first embodiment.

FIG. 5 is a diagram explaining the manufacturing process of the semiconductor device according to the first embodiment.

FIG. 6 is a diagram explaining a first example of the recess pattern of the semiconductor device according to the first embodiment.

FIG. 7 is a diagram explaining a second example of the recess pattern of the semiconductor device according to the first embodiment.

FIG. 8 is a diagram explaining a third example of the recess pattern of the semiconductor device according to the first embodiment.

FIG. 9 is a diagram explaining a fourth example of the recess pattern of the semiconductor device according to the first embodiment.

FIG. 10 is a diagram explaining another example of the formation area of the recess pattern in the semiconductor device according to the first embodiment.

FIG. 11 is a diagram explaining another example of a formation area for a recess pattern in a semiconductor device according to the first embodiment.

FIG. 12 is a cross-sectional view of a semiconductor device according to the second embodiment.

### DETAILED DESCRIPTION

For clarity of explanation, the following description and drawings are appropriately omitted and simplified. In each drawing, the same elements are assigned the same reference numerals, and redundant explanations are omitted as necessary. Specifically, the shapes represented in the drawings described below are simplified for explanatory purposes, and it should be noted that the number, size, and density of recesses RP are determined by the product specifications of the semiconductor device, which may differ from the number, size, and density shown in the drawings.

### FIRST EMBODIMENT

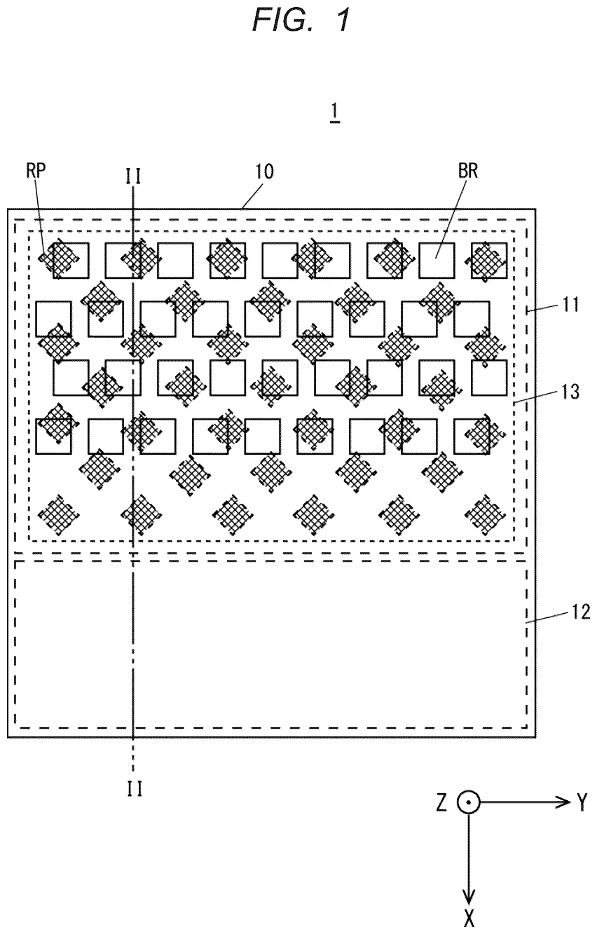

FIG. 1 shows a schematic diagram of a semiconductor device 1 according to the first embodiment. The schematic diagram shown in FIG. 1 represents a semiconductor chip 10 viewed from above the first surface side where circuit elements are formed on the semiconductor substrate, and also shows the positions of recesses RP formed on the second surface side opposing the first surface.

As shown in FIG. 1, a semiconductor chip 10 has a power transistor formation area 11 and a control logic formation area 12 on the first surface, and a backside recess pattern formation area 13 on the second surface. The power transistor formation area 11 is where vertical transistors, which conduct current in the thickness direction (Z direction in FIG. 1) of the semiconductor substrate, are formed. It should be noted that vertical transistors are power transistors capable of conducting larger currents than lateral transistors, and in the following description, vertical transistors are referred to as power transistors. Additionally, a bonding area BR, which serves as an end region supplying current to the source terminal of the power transistor, is formed in the power transistor formation area 11.

The control logic formation area 12 is where lateral transistors, which conduct current in the horizontal direction (X direction or Y direction in FIG. 1) of the semiconductor substrate, are formed. In the semiconductor device 1 according to the first embodiment, the circuit formed in the control logic formation area 12 controls the power transistor formed in the power transistor formation area 11.

The backside recess pattern formation area 13 is set to a narrower area than the power transistor formation area 11, and multiple recesses RP are formed. The outer periphery defining the power transistor formation area 11 is set at a position a predetermined distance (for example, 100 micrometers or more) away from the outer periphery of the semiconductor chip 10.

Here, the single-crystal silicon constituting the semiconductor substrate has the characteristic that the mobility of charge carriers differs according to the silicon crystal lattice. Specifically, Miller indices representing the faces and orientations of the crystal lattice are known, and the direction along the <100> face has the highest charge carrier mobility. Therefore, in semiconductor device 1 having power transistors, the direction of the vertical channel of the power transistor is aligned with the <100> face of the single-crystal silicon constituting the semiconductor substrate. Moreover, it is known that the etching rate during the etching process in the manufacturing process significantly differs due to the difference in Miller indices (difference in crystal orientation) of the single-crystal silicon. When focusing on this difference in etching rate, it is preferable that the bottom surface of the recess RP is set to a surface orthogonal to the <100> face, and the sidewalls of the recess RP are set to surfaces orthogonal to the <111> face. However, when the etching pattern of the second surface or the side extension direction of the shape pattern of the recess RP is made the same as that of the first surface, which prioritizes the transistor performance of the semiconductor substrate, it becomes difficult to set the etching progression direction to the <111> plane direction, and a problem of etching unevenness was found.

Therefore, in the semiconductor device 1 according to the first embodiment, the configuration is such that the side extension direction of the pattern of the recess RP formed on the second surface side is shifted relative to the side extension direction of the element pattern or wiring pattern formed on the first surface side. In FIG. 1, while the pattern of the bonding region BR formed on the first surface side is square, the recess RP formed on the second surface side is in a diamond shape rotated from the square. Thus, in the semiconductor device 1 according to the first embodiment, the side extension direction of the pattern of the recess RP formed on the second surface side has a rotated relationship with respect to the side extension direction of the element pattern or wiring pattern formed on the first surface side. Furthermore, the recess RP is an independent pattern from the element pattern, wiring pattern, and bonding region BR on the first surface side, and is patterned independently of the pattern on the first surface. The following describes the configuration of the recess RP in detail.

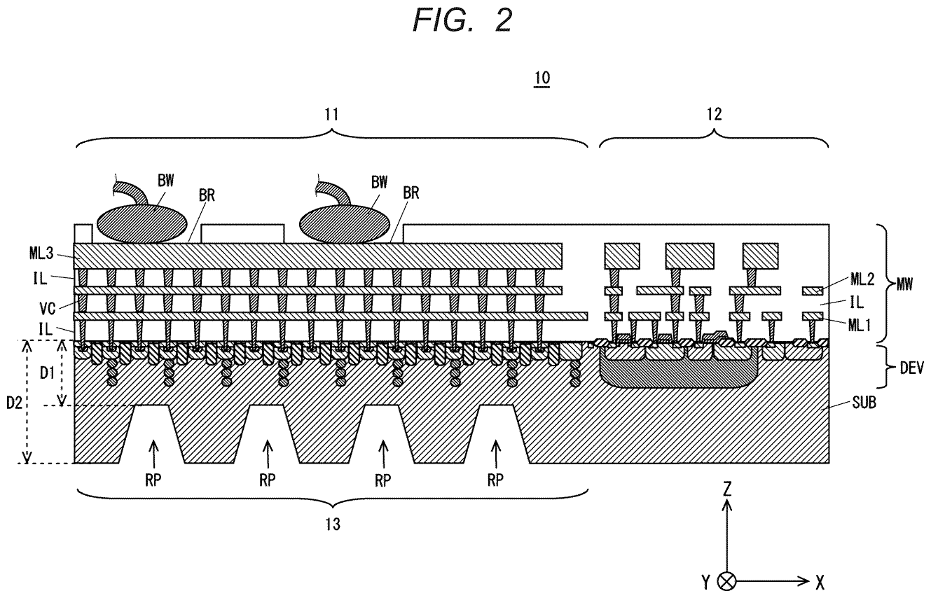

FIG. 2 shows a cross-sectional view of the semiconductor device 1 according to the first embodiment. The cross-sectional view shown in FIG. 2 schematically illustrates the cross-sectional structure of the semiconductor chip 10 along line II-II in FIG. 1. As shown in FIG. 2, semiconductor chip 10 has a power transistor formation region 11, a control logic formation region 12, and a back surface recess pattern formation region 13.

In the semiconductor chip 10, on the surface of the first side of the semiconductor substrate SUB, an element formation layer DEV is formed. A power transistor is formed in the portion corresponding to the power transistor formation region 11 of the element formation layer DEV. In the example shown in FIG. 2, an example is shown where a trench-type power transistor with a gate electrode embedded in a trench is formed. A lateral transistor is formed in the portion corresponding to the control logic formation region 12 of the element formation layer DEV.

A wiring formation layer MW is formed on the upper layer of the first side of the semiconductor substrate SUB. In the example shown in FIG. 2, an example is shown where the first layer wiring ML1, the second layer wiring ML2, the third layer wiring ML3, and the bonding region BR are formed in the wiring formation layer MW. Transistors formed on the semiconductor substrate SUB, the first layer wiring ML1, the second layer wiring ML2, and the third layer wiring ML3 are insulated from each other by an interlayer insulating film IL, while being electrically connected to each other through vias VC that penetrate the interlayer insulating film IL.

Also, as shown in FIG. 2, on the topmost layer of the wiring formation layer MW in power transistor formation region 11, a bonding region BR is formed, which is an end region for supplying current to the source terminal of the power transistor. FIG. 2 shows a state where a bonding wire BW is bonded to the bonding region BR to connect the bonding region BR with a lead frame.

As shown in FIG. 2, multiple recesses RP are formed in the back surface recess pattern formation region 13 on the second surface side of the semiconductor substrate SUB. The recess RP has a shape that recesses from the second surface of the semiconductor substrate SUB towards the first surface. In the portion where the recess RP is formed, the thickness of the semiconductor substrate SUB is reduced, and the resistance caused by the semiconductor substrate SUB is reduced. It is preferable that the thickness D1 from the bottom of the recess RP to the surface of the first surface of the semiconductor substrate SUB is a quarter or less of the thickness D2 from the flat surface of the second surface around the recess RP to the surface of the first surface of the semiconductor substrate SUB, and more preferably about one-fifth (for example, if the thickness D2 is 150 micrometers, the thickness D1 is about 30 micrometers).

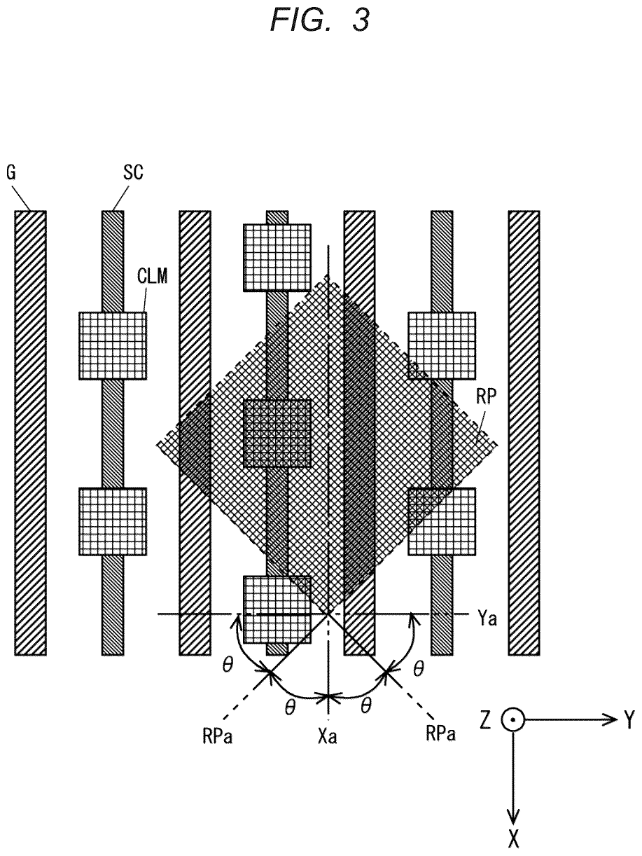

Next, the relationship between the device pattern formed on the first surface and the pattern of the recess RP formed on the second surface will be described in detail. FIG. 3 shows a diagram explaining the relationship between the device pattern and the recess pattern formed in the semiconductor device according to the first embodiment. In FIG. 3, the device pattern on the first surface of the power transistor and the pattern of the recess RP are shown as the device pattern formed on the first surface.

In the example shown in FIG. 3, the gate electrode G, source contact SC, and column CLM of the power transistor are shown. These device patterns are formed on the surface of the first surface. And the extending directions Xa, Ya of the sides of these device patterns are set parallel to the X and Y directions, which are parallel to the outer peripheral side of the semiconductor chip 10.

On the other hand, the extending direction RPa of the sides of the pattern of the recess RP is set to be shifted by a rotation angle θ (theta) from the extending directions Xa, Ya of the sides of the device pattern. This rotation angle θ (theta) is an angle determined by the plane orientation of single-crystal silicon, and in semiconductor device 1 according to the first embodiment, 45 degrees) (45°) is preferred.

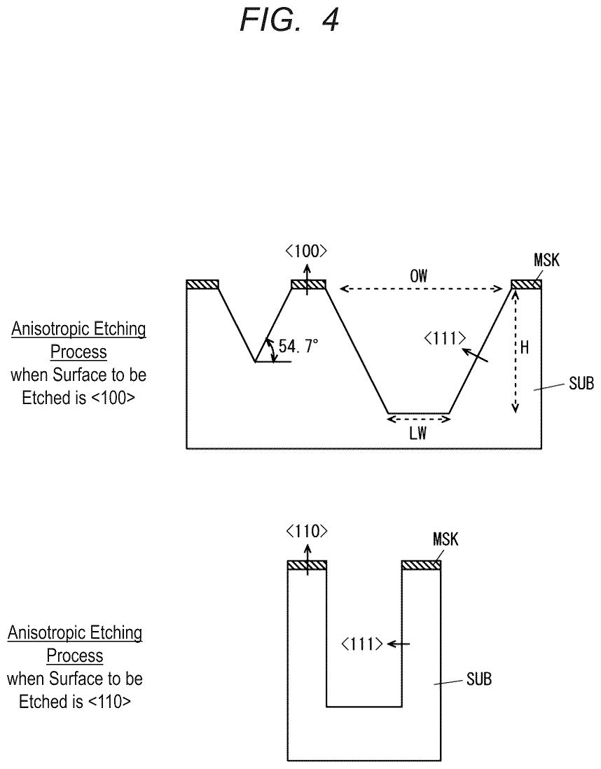

Next, the plane orientation of single-crystal silicon and anisotropic etching will be described. Therefore, FIG. 4 shows a diagram explaining the anisotropic etching process used in semiconductor device 1 according to the first embodiment. First, when forming the recess RP in semiconductor device 1 according to the first embodiment, anisotropic etching by wet etching is performed. In this anisotropic etching, tetramethylammonium hydroxide (TMAH) is used as the etching solution. When etching is performed using TMAH, the etching rate for surfaces perpendicular to the <100> plane of single-crystal silicon becomes significantly slower than for surfaces perpendicular to the <111> plane. Here, if etching is performed on surfaces perpendicular to the <111> plane, with the surface perpendicular to the <100> plane of single-crystal silicon being the flat surface of the second surface, the angle formed between the wall of the recess and the flat surface of the second surface is equal to or more than 50 degrees and less than 60 degrees, about 55 degrees, more precisely 54.7 degrees.

Also, when etching is performed using TMAH, the etching rate for surfaces perpendicular to the <111> plane of single-crystal silicon becomes significantly slower than for surfaces perpendicular to the <110> plane.

Due to such differences in etching rates, when etching is performed on the semiconductor substrate SUB with the surface perpendicular to the <100> plane being the surface of the second surface using TMAH, a trapezoidal or triangular trench with the mask MSK opening as the base is formed. Furthermore, when etching is performed on a semiconductor substrate SUB with a surface orthogonal to the <110> plane as the surface of the second surface using TMAH, a rectangular trench is formed that appears to be dug straight down in the shape of the mask MSK opening.

In the semiconductor device 1 according to the first embodiment, in order to use the <100> plane for the charge transfer path of the power transistor, the second surface must be a plane orthogonal to the <100> plane. That is, in semiconductor device 1 according to the first embodiment, the recess RP has a trapezoidal cross-sectional shape where the wall surface shown in the upper figure of FIG. 4 is orthogonal to the <111> plane. Here, when the opening of the mask MSK is made square, the shape of the recess RP becomes a truncated pyramid with the length of each side of the opening being the width OW, the depth being H, and the length of each side of the bottom surface being the width LW.

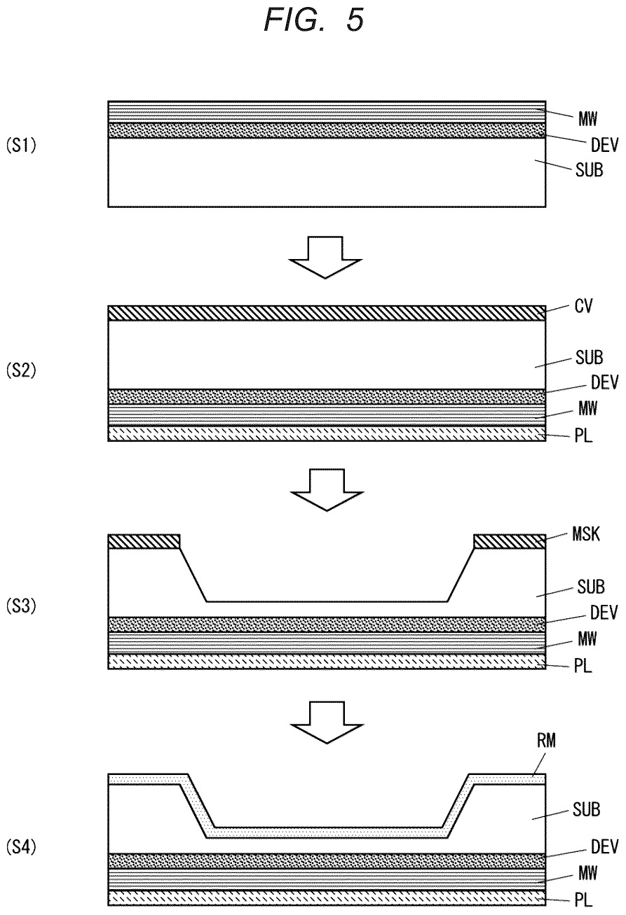

Next, the manufacturing method of semiconductor device 1 according to the first embodiment will be described. FIG. 5 shows a diagram explaining the manufacturing process of the semiconductor device according to the first embodiment. In FIG. 5, four steps S1 to S4 are illustrated, but one step may include multiple processes.

Specifically, step S1 includes a device formation process and a wiring formation process. In the device formation process, transistors are formed on the first surface of the semiconductor substrate. In this device formation process, not only vertical transistors but also horizontal transistors may be formed. This device formation process forms circuit elements such as transistors in the device formation layer DEV. In the wiring formation process, wiring and bonding areas related to the transistors are formed on the first surface. Thus, the wiring formation layer MW is formed.

Subsequently, step S2 includes a surface protection layer formation process. In the surface protection layer formation process, a surface protection layer PL is formed on the surface of the wiring and bonding areas. Also, in step S2 shown in FIG. 5, after the surface protection layer formation process, a process of forming a CVD (Chemical Vapor Deposition) film CV as a mask MSK on the second surface of the semiconductor substrate SUB is illustrated. This CVD film CV is deposited on the second surface of the semiconductor substrate SUB with the surface protection layer PL underneath.

Subsequently, step S3 includes a mask pattern formation process and an etching process. In the mask pattern formation process, a mask pattern corresponding to the openings of multiple recesses is formed on the second surface of the semiconductor substrate SUB, which faces the first surface. In the etching process, the exposed semiconductor substrate SUB at the openings of the mask MSK is etched by wet etching with TMAH (Tetramethylammonium hydroxide). This etching process forms the recess RP of the semiconductor device 1 according to the first embodiment.

Subsequently, step S4 to be performed includes a mask pattern removal process and a backside plating process. In the mask pattern removal process, the CVD film remaining as the mask MSK is removed. In the backside plating process, a metal layer (for example, backside metal plating RM) is formed on the second surface. This backside metal plating RM serves as a backside electrode and also improves the adhesiveness of the paste material applied when mounting the semiconductor chip 10 on the lead frame.

From the above description, in the semiconductor device 1 according to the first embodiment, by offsetting the extending direction of the sides of the pattern forming the recess RP on the second surface of the semiconductor substrate SUB from the extending direction of the sides of the pattern formed on the first surface, it is possible to suppress etching unevenness during the etching process used to form the recess RP. As a result, in the semiconductor device 1 according to the first embodiment, it becomes possible to form the shape of the recess RP as designed.

Furthermore, the semiconductor device 1 having the recess RP can ensure performance with excellent low resistance by reducing the thickness of the semiconductor substrate SUB, which becomes the drain region of the power transistor. In the example shown in FIG. 1, multiple recesses RP are formed in a lattice pattern. By forming the recesses RP in such a lattice pattern, the semiconductor substrate SUB in the lattice parts acts as a frame, making it possible to prevent damage to the semiconductor chip 10.

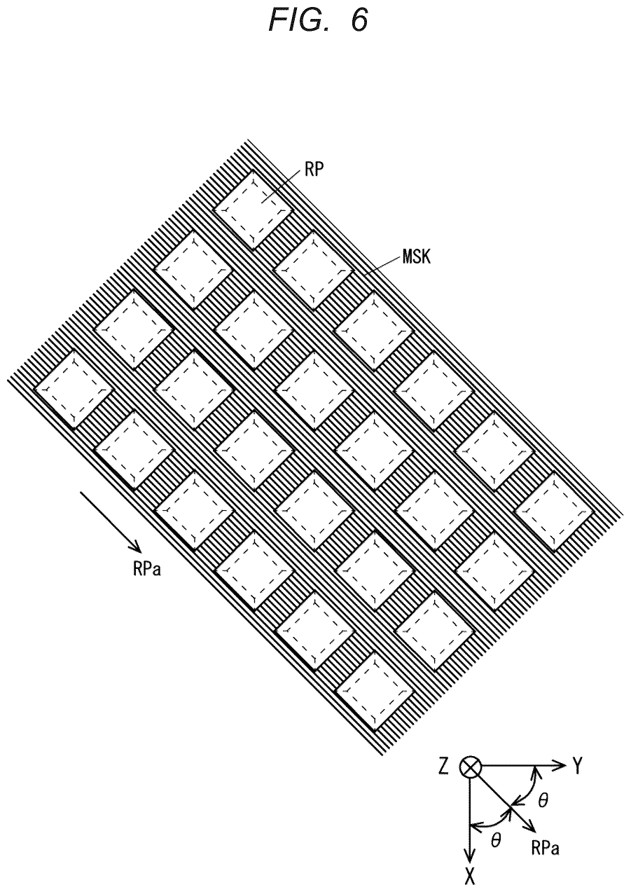

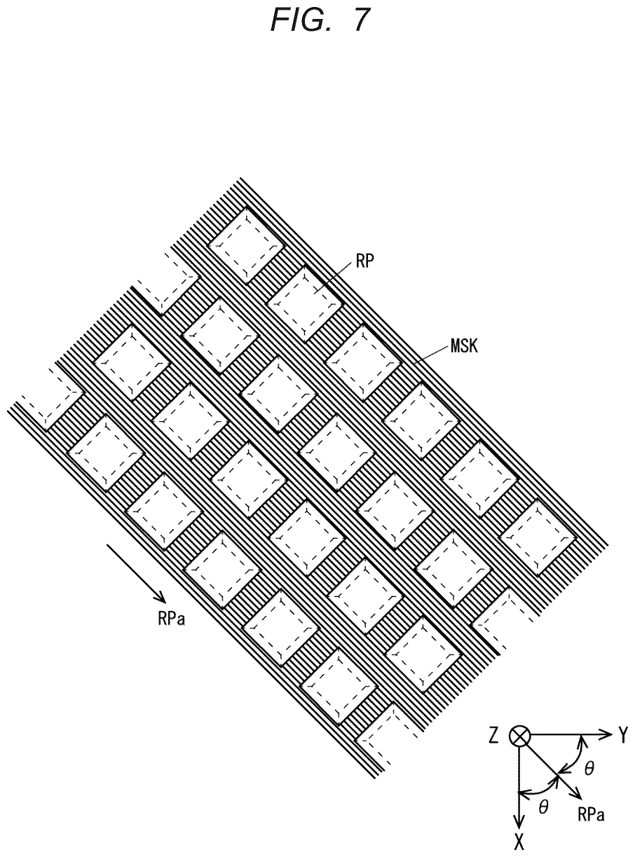

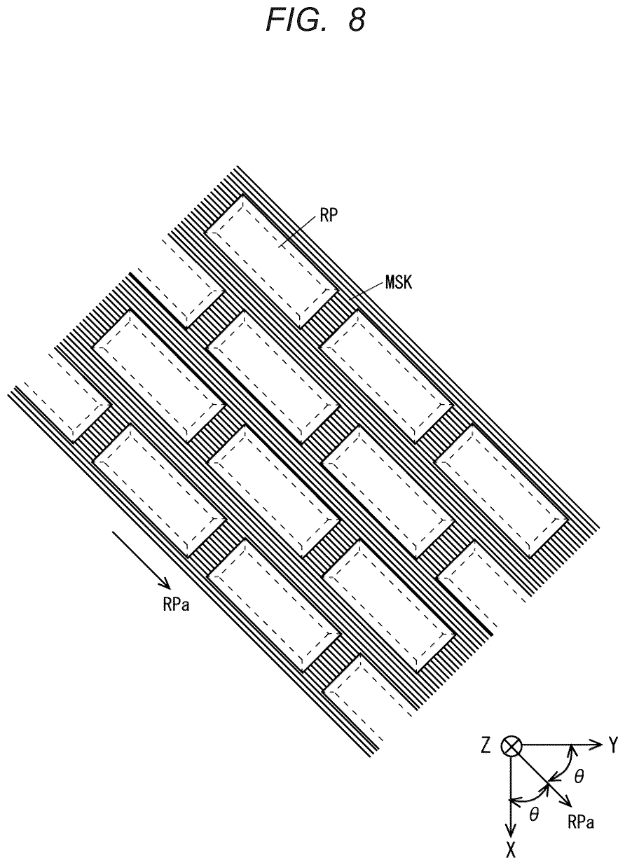

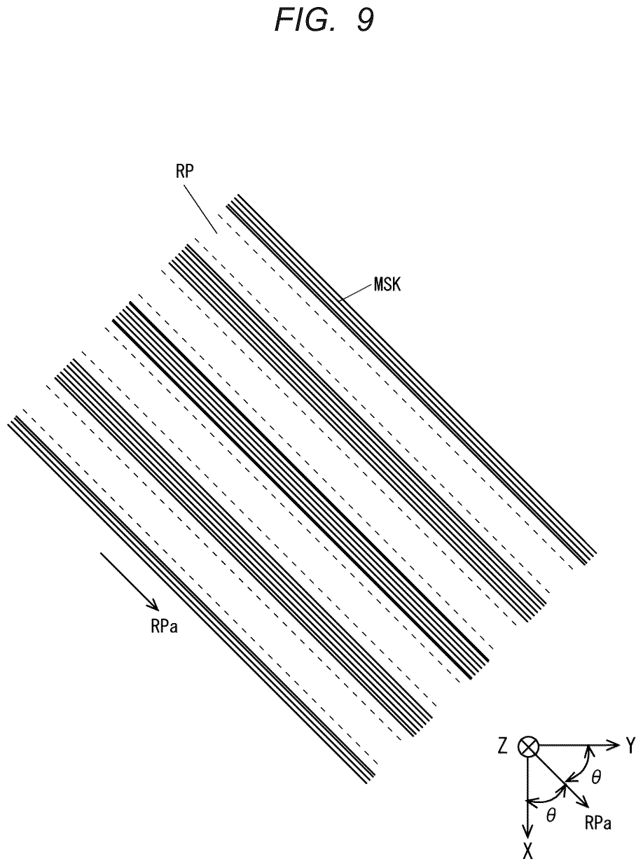

Since various shapes can be considered for the pattern forming the recess RP, an example of a modified example of the formation pattern of the recess RP is shown in FIGS. 6 to 9. FIG. 6 is a diagram explaining the first example of the recess pattern of the semiconductor device according to the first embodiment, where, as in FIG. 1, the pattern in which the recess RP is formed is surrounded by a lattice-shaped mask MSK. FIG. 7 is a diagram explaining the first example of the recess pattern of the semiconductor device according to the first embodiment. In the second example shown in FIG. 6, the pattern in which the recess RP is formed is surrounded by a zigzag-shaped mask MSK. FIG. 8 is a diagram explaining the third example of the recess pattern of the semiconductor device according to the first embodiment. The third example shown in FIG. 8 is a pattern in which each recess RP has a rectangular shape and is formed to be surrounded by a zigzag-shaped mask MSK. FIG. 9 is a diagram explaining the fourth example of the recess pattern of the semiconductor device according to the first embodiment. The third example shown in FIG. 9 has trenches extending in one direction, which have a shape that continues in a direction perpendicular to the direction in which the trenches extend, in this case, the mask MSK is formed to partition these trenches. In any of the examples shown in FIGS. 6 to 9, the extending direction RPa of the side of the mask pattern is set to have a rotation angle θ (theta) (for example, 45 degrees) relative to the X direction or Y direction, which is the extending direction of the side of the element or wiring pattern on the first surface.

Thus, although various forms can be considered for the shape and arrangement method of the recesses RP, since the thickness of the semiconductor substrate SUB, which becomes the part of the drain terminal of the power transistor, can be reduced in all cases, it is possible to obtain the effect of improved low resistance of the power transistor and ensured substrate strength, similar to the semiconductor device 1 described in FIGS. 1 to 5.

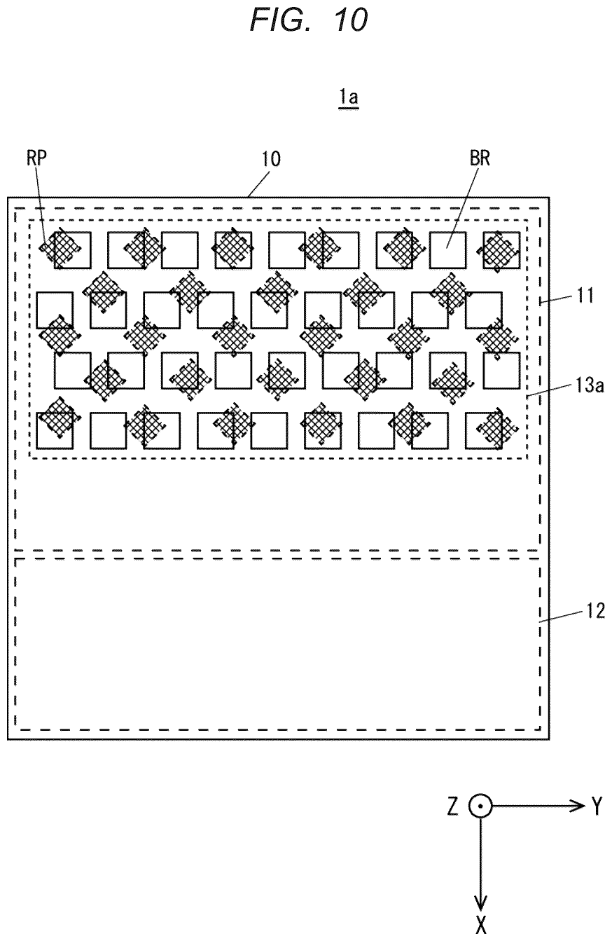

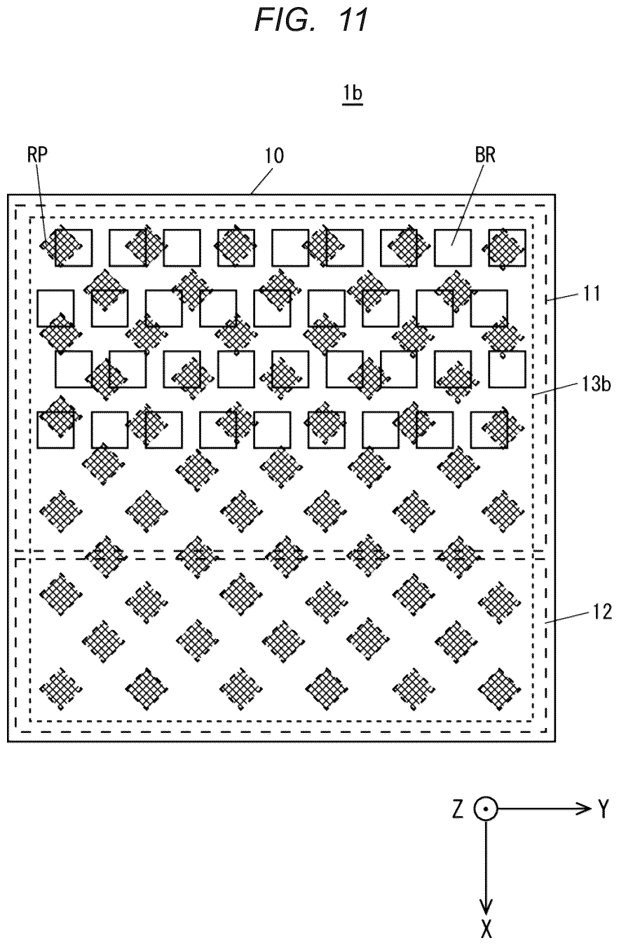

Moreover, various forms can be considered for how to set the back surface recess pattern formation area 13 for forming the recess RP. Therefore, modified examples of the back surface recess pattern formation area 13 are shown in FIGS. 10 and 11.

FIG. 10 is a diagram explaining another example of the formation area of the recess pattern in the semiconductor device according to the first embodiment. In the first example shown in FIG. 10, the back surface recess pattern formation area 13a is set so that the recess RP is primarily located on the second surface facing the area where the bonding region BR, which has a particularly high current density, is placed.

FIG. 11 is a diagram explaining another example of a recess pattern formation area in the semiconductor device according to the first embodiment. In the second example shown in FIG. 11, an example is shown where a backside recess pattern formation area 13b is set also in an area including the area facing the control logic formation area 12 on the second surface of the semiconductor substrate SUB. In this second example, a recess RP is formed also on the second surface facing the control logic formation area 12.

Thus, the extent of the area in which the recess RP is formed is adjusted based on the balance between the low resistance performance required by the power transistor and the heat dissipation performance of the semiconductor device 1, with no difference in the fundamental effect of forming the recess RP.

### Second Embodiment

In the second embodiment, a semiconductor device 2, which mounts the semiconductor device 1 according to the first embodiment on a lead frame, is described. In the description of the second embodiment, components described in the first embodiment are denoted by the same reference numerals, and the description thereof is omitted.

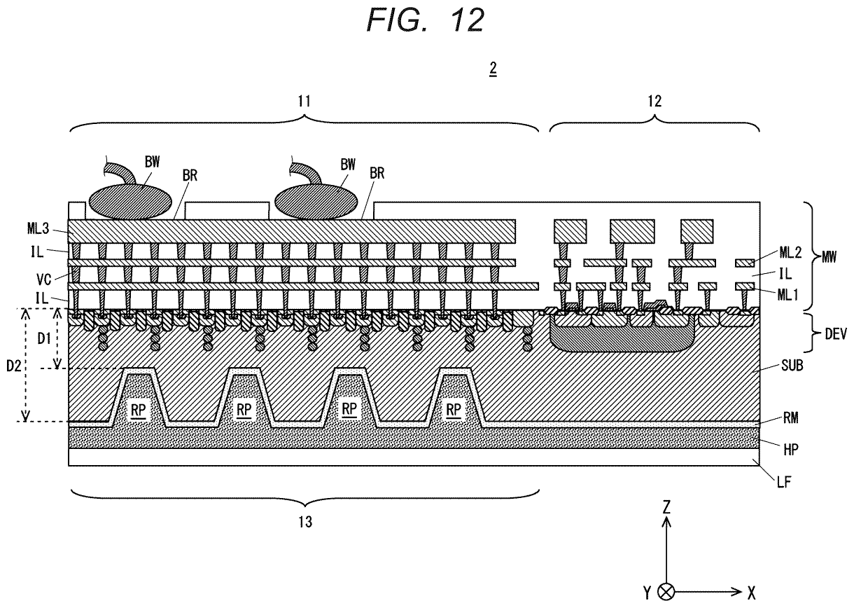

FIG. 12 shows a cross-sectional view of the semiconductor device according to the second embodiment. The semiconductor chip 10 shown in FIG. 12 is the semiconductor chip 10 described in FIG. 2 with a backside metal plating RM formed thereon. In semiconductor device 2 according to the second embodiment, a thermally conductive paste material HP is interposed between the backside metal plating RM and the lead frame LF. This thermally conductive paste material has a lower thermal conductivity and a lower electrical resistance than the semiconductor substrate SUB, and is, for example, a paste material mainly composed of silver.

In this way, by interposing the thermally conductive paste material HP between the backside metal plating RM and the lead frame LF, the thermally conductive paste material HP enters the recess RP, and the paste material transfers electricity and heat to the lead frame LF. Furthermore, by using the thermally conductive paste material HP, which has a lower thermal conductivity and a lower electrical resistance than the semiconductor substrate SUB, it is possible to enhance the low resistance performance of the power transistor and improve the heat dissipation of the semiconductor device 2 as a whole.

When forming the semiconductor device 2, a paste application step and a chip mounting step are added to the manufacturing process described in FIG. 5. In the paste application step, a paste material (thermally conductive paste material HP) with lower thermal conductivity than the semiconductor substrate SUB is applied to the surface of the metal layer (for example, the backside metal plating RM). In the chip mounting step, the semiconductor substrate SUB is placed on the lead frame LF via the thermally conductive paste material HP.

As described above, the invention made by the inventor has been specifically described based on the embodiment, but the present invention is not limited to the embodiments already described, and it is needless to say that various modifications can be made without departing from the gist thereof.

What is claimed is:

1. A semiconductor device comprising:
a semiconductor substrate having a first surface where a source terminal and a gate electrode of a vertical transistor are formed, and a second surface where a drain terminal of the vertical transistor is formed;
a bonding region formed on an upper surface of a region where the source terminal is formed on the first surface side, to which a bonding wire for supplying current to the source terminal is connected; and
a plurality of recesses formed in a region on the second surface, the region at least including a region facing the first surface where the bonding region is formed, on the second surface,
wherein an extending direction of an outer peripheral side of an opening of the plurality of recesses is set in a direction mismatched with an extending direction of a side of an element pattern formed on the first surface.

2. The semiconductor device according to claim 1, wherein the extending direction of the outer peripheral side of the opening of the plurality of recesses is set in a direction rotated by 45 degrees with respect to the extending direction of the side of the element pattern formed on the first surface.

3. The semiconductor device according to claim 1, wherein walls of the plurality of recesses are surfaces orthogonal to <111> plane of single crystal silicon, and a flat surface of the second surface is a surface orthogonal to <100> plane of the single crystal silicon.

4. The semiconductor device according to claim 1, wherein the plurality of recesses has a shape of a lattice, a staggered shape, or a plurality of trenches continuously extending in a direction orthogonal to the extending direction.

5. The semiconductor device according to claim 1, wherein the plurality of recesses has the shape of a truncated pyramid with a flat bottom surface.

6. The semiconductor device according to claim 1, wherein walls of the plurality of recesses have an inclination of 50 degrees to 60 degrees with respect to a flat surface of the second surface.

7. The semiconductor device according to claim 1, wherein the plurality of recesses is formed in a region on the second surface facing the region where the vertical transistor is formed.

8. The semiconductor device according to claim 1, wherein a control logic formation region is formed on the first surface, where a horizontal transistor that constitutes a control circuit of the vertical transistor as a control part is formed, and
wherein the plurality of recesses is also formed in a region on the second surface including a region facing the control logic formation region.

9. The semiconductor device according to claim 1, wherein the second surface is bonded to a lead frame via a paste material with a lower thermal conductivity than the semiconductor substrate.

10. The semiconductor device according to claim 1, wherein the region where the plurality of recesses is formed is set at a position more than 100 micrometers away from an edge of the semiconductor substrate.

11. The semiconductor device according to claim 1, wherein a thickness from a bottom surface of the plurality of recesses to a surface of the first surface of the semiconductor substrate is less than or equal to one-fourth of a thickness from a flat surface of the second surface around the plurality of recesses to a surface of the first surface of the semiconductor substrate.

12. A method of manufacturing a semiconductor device, the method comprising:
element formation of forming a transistor on a first surface of a semiconductor substrate;
wiring formation of forming a wiring and a bonding region related to the transistor on the first surface;
surface protection layer formation of forming a surface protection layer on a surface of the wiring and the bonding region;
mask pattern formation of forming a mask pattern on a second surface facing the first surface of the semiconductor substrate, corresponding to openings of the plurality of recesses;
etching the exposed semiconductor substrate at the openings by wet etching with TMAH (Tetramethylammonium hydroxide); and
mask pattern removal of removing the mask pattern,
wherein an extending direction of a side of the openings of the mask pattern is set in a direction mismatched with an extending direction of a side of an element pattern formed on the first surface.

13. The method according to claim 12, wherein the extending direction of the side of the openings of the mask pattern is set in a direction rotated by 45 degrees relative to the extending direction of the side of the element pattern formed on the first surface.

14. The method according to claim 12, wherein walls of the plurality of recesses are surfaces orthogonal to <111> plane of single crystal silicon, and a flat surface of the second surface is a surface orthogonal to <100> plane of the single crystal silicon.

15. The method according to claim 12, further comprising, after the mask pattern removal,
backside plating of forming a metal layer on the second surface,
paste application of applying a paste material with a lower thermal conductivity than the semiconductor substrate on a surface of the metal layer, and
chip mounting of placing the semiconductor substrate on a lead frame via the paste material.
